(19) United States
(12) Patent Application Publication
(10) Pub. No.: US 2026/0223601 A1
(43) Pub. Date: Jul. 30, 2026

(54) A MAGNON-MEDIATED SPIN TORQUE SWITCHING DEVICE

(71) Applicant: NATIONAL UNIVERSITY OF SINGAPORE, Singapore (SG)

(72) Inventors: Hyunsoo YANG, Singapore (SG); Fei WANG, Singapore (SG); Guoyi SHI, Singapore (SG)

(73) Assignee: NATIONAL UNIVERSITY OF SINGAPORE, Singapore (SG)

(21) Appl. No.: 19/158,260

(22) PCT Filed: Feb. 28, 2024
(86) PCT No.: PCT/SG2024/050112

§ 371 Date: Aug. 20, 2025

(30) Foreign Application Priority Data
Feb. 28, 2023 (SG) 10202300540R

(51) Int. Cl. H10N 50/10; G11C 11/16; H10N 50/85

(52) U.S. Cl. CPC H10N 50/10; G11C 11/161; G11C 11/1673; H10N 50/85

(57) ABSTRACT

Disclosed is a magnon-mediated spin torque switching device. The device comprises a spin source layer connected or connectable to a current source, a magnetic layer and a magnetic insulating layer between the spin source layer and magnetic layer. The magnetic insulating layer prevents passage of electrical current from the spin source layer to the magnetic layer.

### TECHNICAL FIELD

This disclosure generally relates to magnon-mediated spin torque switching devices and memory devices comprising a magnon-mediated spin torque switching devices.

### BACKGROUND

This background description is provided for the purpose of generally presenting the context of the disclosure. Contents of this background section are neither expressly nor impliedly admitted as prior art against the present disclosure.

Spintronics aims to fabricate low power-consumption and magnetic-field-free magnetic logic and memory devices. Spin-transfer torque (STT) is an effect in which the orientation of a magnetic layer in a magnetic tunnel junction or spin valve can be modified using a spin-polarised current. Spin-transfer torque magnetic random access memory (STT-MRAM) is a non-volatile memory with near-zero leakage power consumption. The STT-MRAM based on the magnetic tunnel junction structure, while commercially available, suffers from several limitations, e.g., reliability, and nanosecond-scale incubation delay issues.

The spin-orbit torque magnetic random-access memory (SOT-MRAM) can avoid these issues. In a SOT structure, the charge current flows in the spin source layer and generates a spin current due to spin-orbit interaction. The spin current exerts torques on the adjacent ferromagnetic layer and enables switching of the magnetisation. However, the electron-mediated spin torque, which involves moving charges, results in inevitable Joule heating and corresponding energy dissipation.

It is desired to address or ameliorate one or more disadvantages or limitations associated with previous switching devices and memory devices, or to at least provide a useful alternative.

### SUMMARY

Electron-mediated spin torque results in Joule heating and corresponding energy dissipation. The present disclosure provides a device that seeks to circumvent Joule heating by magnon-mediated spin torque. Magnon-mediated spin torque involves magnon currents, where the spin angular momentum is carried by spin waves instead of moving electrons. Therefore, magnon currents may enable Joule-heating-free transfer of spin angular momentums. It follows that using magnon torques instead of electron-mediated torques can reduce the power consumption of MRAM devices.

Thus, disclosed herein is a magnon-mediated spin torque switching device, comprising:
a spin source layer connected or connectable to a current source;
a magnetic layer; and
a magnetic insulating layer between the spin source layer and magnetic layer, for preventing passage of electrical current from the spin source layer to the magnetic layer.

The spin source layer may be a topological material such as a topological insulator or Weyl semimetal.

The spin source layer may be 8 nm thick.

The spin source layer may comprise at least one of BiSb, Bi₂Se₃, Bi₂Te₃, Sb₂Te₃, MoTe₂, WTe₂, TaIrTe₄, and PtTe₂.

The spin source layer may have a crystal structure selected to generate out-of-plane spin.

The spin source layer may comprise a bilayer. The bilayer may comprise two van der Waals materials. The bilayer may comprise heterostructures comprising layers of different crystal symmetries. The bilayer may comprise a symmetry broken layer and a centrosymmetric layer. The bilayer may be a WTe₂/PTe₂ heterostructure.

A thickness of the magnetic insulating layer may be selected to maximise spin torque ferromagnetic resonance.

The magnetic insulating layer may be between 1 nm and 40 nm thick, preferably between 20 nm and 30 nm thick, and more preferably around 25 nm thick.

The spin source layer and magnetic insulating layer may form a rectangular or cross-shape.

The magnetic layer may comprise a magnetic dot at a centre of the rectangular or cross-shape.

The magnetic insulating layer may comprise NiO or other metals or transition metal oxides. The other metals or transition metal oxides may comprise one of the following metals or transition metal oxides: Fe₂O₃, CoO, Cr₂O₃, MnO₂, RuO₂, BiFeO₃, DyFeO₃, TmFeO₃, YbFeO₃, CuMnAs, MnTe, MnTe₂, CrSb, and Mn₂Au.

The magnetic layer may be a ferromagnetic layer with perpendicular magnetisation.

Also disclosed is a memory comprising:
a magnon-mediated spin torque switching device according to any one of the above;
a current source connected to the spin source layer; and
a reader for reading a magnetisation direction of the magnetic layer.

The memory may be a magnetoresistive random access memory (MRAM) device.

In some embodiments the information storage layer (magnetic layer) does not need to be electrically connected to the electron injection layer (spin source layer), therefore relaxing a complex interconnect/via issue in modern nano-electronics architectures.

Advantageously, the present invention uses magnon-mediated spin torques. This avoids Joule heating caused by charge movement in previous switching devices.

Advantageously, embodiments of the invention use high spin Hall conductivity materials with out-of-plane spins. This results in low power consumption field-free switching of perpendicular magnetisation.

Advantageously, embodiments of the invention facilitate room temperature switching of perpendicular magnetisation by magnon torques.

### BRIEF DESCRIPTION OF THE DRAWINGS

Some embodiments of switching devices and corresponding experimental results will now be described, by way of non-limiting example only, with reference to the accompanying drawings in which:

FIG. 1 shows ST-FMR spectra from the Bi₂Te₃ (8 nm)/NiO (d)/Ni₈₁Fe₁₉ (6 nm) samples. (a) Schematic diagram of the ST-FMR layer structure (left), and the measurement circuit connected to a ST-FMR device (right). (b) Typical ST-FMR signal of the Bi₂Te₃ (8 nm)/NiO (25 nm)/Ni₈₁Fe₁₉ (6 nm) device measured at 9 GHz. The solid lines are fits that show the symmetry (V_{S}F_{S}) and anti-symmetry (V_{A}F_{A}) Lorentzian contributions. (c) The spin torque efficiency θ_{ST}, the terahertz emission amplitude and the coercivity H_{c} of the Ni₈₁Fe₁₉ (inset) versus NiO thickness, d. The red line is an exponential decay fitting of θ_{ST}.

FIG. 2 is a schematic of magnon torque switching and sample characterisation. (a) Schematic of magnon-induced switching of CoFeB layer. The CoFeB exhibits perpendicular magnetic anisotropy (PMA). (b) High-resolution cross sectional transmission electron microscopy image of Bi₂Te₃ (8 nm)/NiO (25 nm)/CoFeB, where the interfaces are indicated by the white dashed lines.

FIG. 3 illustrates the results of magnon-induced magnetisation switching in the Bi₂Te₃ (8 nm)/NiO (25 nm)/CoFeB sample. (a) Anomalous Hall curve measured by sweeping magnetic field along the out-of-plane (z) direction. (b) Magnon-induced spin torque switching under 10 mT, 0 mT, and −10 mT in-plane magnetic fields μ₀Hₓ. (c) μ₀Hₓ dependence of critical switching current density J_{C}.

FIG. 4 shows magnon-mediated spin torque switching captured by magneto-optical Keer effect (MOKE) microscopy. (a) Schematic of CoFeB magnetic dots on top of Bi₂Te₃/NiO. (b) M-μ₀H curve measured by applying the magnetic field along the z-direction. (c) MOKE images of switching the magnetisation of CoFeB magnetic dots by applying a pulse current along the x-axis and with an external field of 10 mT along the x direction. (d) MOKE images of CoFeB magnetisation switching with a current pulse along the x-axis and −10 mT external field along the x direction. Black and white contrasts indicate the magnetisation pointing up (+M) and down (−M), respectively.

FIG. 5 shows the crystal symmetry of WTe₂. One is pure mirror Mₓ and the other is a glide mirror M_{y}. The a, b, and c arrows represent the crystal axes.

FIG. 6 shows ST-FMR signals of a WTe₂ (8 nm)/Ni₈₁Fe₁₉ (6 nm) sample. (a) Schematic diagram of the ST-FMR layer structure (left), and the measurement circuit connected to a ST-FMR device (right). (b) φ dependence of V_{S} and V_{A} with currents along the a-axis. (c) φ dependence of V_{S} and V_{A} with currents along the b-axis.

FIG. 7 shows the structural characterisation of WTe₂ films. (a) RHEED patterns of 3 nm WTe₂ film. (b) XRD data from an 8 nm WTe₂ film grown on an Al₂O₃ (001) substrate. (c) Polarised Raman of an 8 nm WTe₂. (d) Terahertz signals from an 8 nm WTe₂ film.

FIG. 8 shows magnon torques-driven switching of perpendicular magnetisation in WTe₂ (8 nm)/NiO (25 nm)/CoFeB heterostructures. (a) Current-induced field-free magnetisation switching of the CoFeB layer. The switching is performed under different angles α between the low-symmetry a-axis of the WTe₂ layer and the current flow direction. (b-d) α dependence of critical switching current density J_{C}, switching ratio R_{S}/R_{H}, and out-of-plane anti-damping effective field μ₀H_{E} with injected current density of 3.2×10⁶ A/cm². The insert in b, illustrates the definition of α.

FIG. 9 shows the NiO thickness dependence of spin-orbit torques. (a) Schematic of the magnon-mediated magnetisation switching based on the WTe₂/NiO/CoFeB sandwich heterostructures. The current is along the a-axis of WTe₂. (b,c) t dependence of R_{S}/R_{H} and J_{C} in the WTe₂ (8 nm)/NiO (t)/CoFeB heterostructures.

FIG. 10 shows polarised Raman of WTe₂ and a PtTe₂/WTe₂ films. (a) Raman spectra of an 8 nm WTe₂ film. The inset is the crystal structure of the WTe₂ with the a-axis and b-axis. The polarisation angle α is defined relative to the a-axis. (b) Contour plot of the

$${A}_{1}^{9}$$

Raman mode as a function of α in the 8 nm WTe₂ sample. (c) Contour plot of the

$${A}_{1}^{9}$$

Raman mode as a function of α in the PtTe₂ (2 nm)/WTe₂ (6 nm) film.

FIG. 11 shows crystal symmetry and spin-orbit torque of the individual WTe₂ or PtTe₂ layer. (a) Crystal structure of WTe₂ (Pmn2₁) and the two mirror symmetries. One is glide mirror M_{y} and the other is pure mirror Mₓ. The a, b, and c arrows represent the crystal axes. (b) ST-FMR spectra from the WTe₂ (8 nm)/Ni₈₁Fe₁₉ (6 nm) sample with currents along the a-axis of the WTe₂ layer. The angle between the magnetic field (μ₀H) and current is 40°. The solid lines are fits that show the symmetry (V_{S}F_{S}) and anti-symmetry (V_{A}F_{A}) Lorentzian contributions.

FIG. 12 illustrates charge conductivity σₓₓ at room temperature. (a) σₓₓ of WTe₂ (t). (b) σₓₓ of PtTe₂ (d). (c) σₓₓ of PtTe₂ (d)/WTe₂ (8-d) bilayer.

FIG. 13 shows the thickness dependence of spin efficiencies. (a) θ_{y}, and θ_{z}, (b) σ_{s,y}, and σ_{s,z} in WTe₂ (t)/Ni₈₁Fe₁₉ (6 nm) samples. The current is along the a-axis of WTe₂. (c,d) θ_{y}, and θ_{s,y} in PtTe₂ (d)/Ni₈₁Fe₁₉ (6 nm) samples. The solid lines are fitting curves with the spin diffusion length (lₛ).

FIG. 14 shows crystal symmetry and spin-orbit torque of the individual WTe₂ or PtTe₂ layer. (a) Crystal structure of PtTe₂ (P3̅m1). PtTe₂ shows an in-plane 3-fold symmetry. (b) ST-FMR spectra from the PtTe₂ (8 nm)/Ni₈₁Fe₁₉ (6 nm) sample.

FIG. 15 illustrates structural characterisation of PtTe₂/WTe₂ bilayers. (a,b) RHEED patterns of the 2 nm PtTe₂ bottom film (a), and 6 nm WTe₂ top film (b) in the PtTe₂ (2 nm)/WTe₂ (6 nm) bilayers. (c) XRD image of the PtTe₂ (8 nm)/WTe₂ (8 nm) bilayers. (d) Cross-sectional TEM image of a PtTe₂ (2 nm)/WTe₂ (6 nm)/Te (12 nm) heterostructure. (e) Corresponding energy dispersive X-ray (EDX) elemental mappings of Pt, W, and Te.

FIG. 16 illustrates spin-orbit torque in PtTe₂/WTe₂ bilayers. (a) PtTe₂ thickness d dependence of in-plane and out-of-plane effective spin efficiencies (θ_{y} and θ_{z}) in PtTe₂ (d)/WTe₂ (8-d)/Ni₈₁Fe₁₉ (6 nm) heterostructures obtained from ST-FMR measurements. (b) d dependence of in-plane (σ_{s,y}) and out-of-plane (σ_{s,z}) spin Hall conductivity in PtTe₂ (d)/WTe₂ (8-d)/Ni₈₁Fe₁₉ (6 nm) heterostructures. (c) Deterministic field-free current-induced magnetisation switching in PtTe₂ (d)/WTe₂ (8-d)/CoFeB heterostructures (d=0, 0.5, 2, 3.5 and 5 nm). (d) Comparison of the normalised power consumption based on PtTe₂ (d)/WTe₂ (8-d)/CoFeB heterostructures (d=0, 0.5, 2, and 3.5 nm).

FIG. 17 shows symmetry-dependent SOT from a PtTe₂/WTe₂ bilayer. (a) Current-induced field-free magnetisation switching in a PtTe₂ (2 nm)/WTe₂ (6 nm)/CoFeB heterostructure. The switching is performed under different angles α between the low-symmetry a-axis of the WTe₂ layer and the current flow direction. (b) α dependence of critical switching current density J_{C}. (c) α dependence of θ_{y} and θ_{z}. The insert illustrates the definition of α.

FIG. 18 provides numerical simulations of SOT switching. (a) Current-induced field-free magnetisation switching with various α. (b) α dependence of J_{C}.

FIG. 19 provides the loop shift results of a PtTe₂ (2 nm)/WTe₂ (6 nm)/CoFeB sample. (a) Anomalous Hall loops under different pulsed d.c. currents. The current is applied along the a-axis. (b) J dependence of μ₀H_{E} obtained from a. (c) α dependence of μ₀H_{E} with J=5.9×10⁶ A/cm².

FIG. 20 shows reflection high energy electron diffraction patterns of an 8 nm Bi₂Te₃ film. The sharp “1×1” diffraction streaks indicate the high quality and smooth surface of the Bi₂Te₃ films grown on sapphire substrates.

FIG. 21 shows atomic force microscope image of an 8 nm Bi₂Te₃ film. The root-mean-square (RMS) roughness (Ra) is ~0.82 nm.

FIG. 22 shows the X-ray diffraction spectroscopy of (a) an 8 nm Bi₂Te₃ and (b) an 8 nm Bi₂Te₃/50 nm NiO film. (00n) peaks of the Bi₂Te₃ layer were observed, indicating that the MBE-grown Bi₂Te₃ films are highly ordered. It also shows the dominant NiO(111) peak.

FIG. 23 shows results for temperature dependent resistivity ρₓₓ of an 8 nm Bi₂Te₃ film. The Bi₂Te₃ sample shows a metallic behaviour at high temperature (T) and an insulating ground state at low T. This insulating ground state is a result of the electron-electron interaction in topological insulator thin films.

FIG. 24 illustrates resistivity ρₓₓ as a function of Bi₂Te₃ thickness t. Thinner Bi₂Te₃ films are more resistive, consistent with the effect of reduced dimensionality.

### DETAILED DESCRIPTION

Electron-mediated spin torque provides a fast and efficient method to manipulate magnetisation, however, electron motion inevitably brings about the generation of Joule heat and corresponding power consumption. Magnon-mediated spin torque devices are therefore described herein. Without involving moving electrons, magnon-mediated spin torque devices could circumvent the energy dissipation issue. Disclosed herein is a sandwich structure of a spin source layer/magnetic insulating layer/magnetic layer. The spin source layer may be a topological material such as a topological insulator or Weyl semimetal. The spin source layer may be a topological insulator Bi₂Te₃, low crystal-symmetry materials WTe₂, a PtTe₂/WTe₂ heterostructure with a high spin Hall conductivity and out-of-plane spins at the same time, but is not limited to these materials as long as the magnon torque can be induced. The magnetic insulating layer may be an antiferromagnetic insulator. The magnetic layer may be a ferromagnet with perpendicular magnetic anisotropy (PMA). The spin source layer may also have a bilayer structures, the heterostructures in the pins source bilayer being layers of, for example, different crystal symmetries.

The magnon current with spin angular momentum was found to traverse the 25-nm-thick antiferromagnetic NiO layer and effectively switch the perpendicular magnetisation of CoFeB at room temperature with a critical switching current density of 4.1×10⁶ A/cm². The magnon torque efficiency is characterised by spin-torque ferromagnetic resonance measurements to be 0.33 with a magnon diffusion length of 26.6 nm.

The present disclosure leverages magnon torque on spin waves. The spin angular momentum is carried by spin waves instead of moving electrons. Therefore, magnon currents may enable Joule-heating-free transfer of spin angular momentums. Moreover, magnon currents have a number of advantages compared with electron currents, such as their long diffusion length, and ultrafast propagation velocity. Moreover, for high-density and fast-speed information storage, the switching of PMA is highly desirable, but technically challenging provided that constructing a PMA layer on top of such a magnon source layer is non-trivial. For practical applications, room temperature magnon driven PMA switching is highly desirable.

The magnetic insulating layer may comprise NiO or other transition metal oxides such as Fe₂O₃, CoO, Cr₂O₃, MnO₂, RuO₂, BiFeO₃, DyFeO₃, TmFeO₃, YbFeO₃, CuMnAs, MnTe, MnTe₂, CrSb, and Mn₂Au. The magnetic layer may be a ferromagnetic layer with perpendicular magnetic anisotropy (PMA).

In a first embodiment, the electron-mediated spin currents generated in the Bi₂Te₃ layer are converted into magnon currents through the interfacial exchange interactions between Bi₂Te₃ and antiferromagnetic NiO. The magnon currents subsequently pass through the NiO layer, exerting magnon torques on the top ferromagnetic layer, and consequently drive the switching of PMA. The NiO layer can be replace by other antiferromagnetic layer as long as magnons can be propagated.

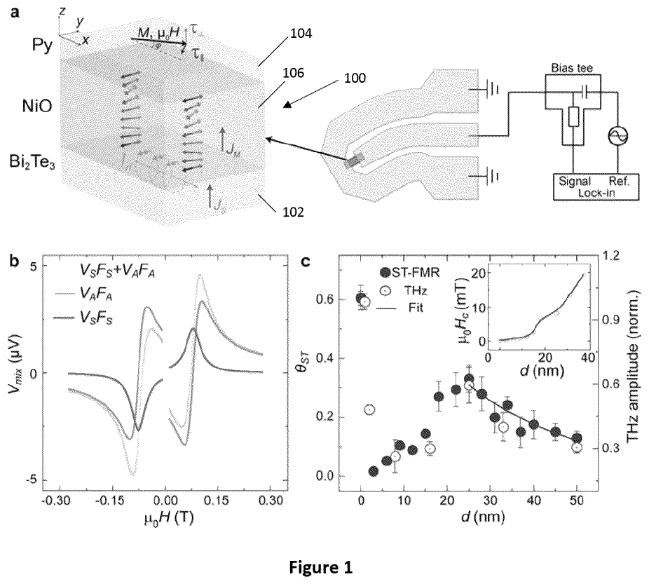

FIG. 1a illustrates a schematic diagram of such a sandwich structure 100 as incorporated into a spin-torque ferromagnetic resonance (ST-FMR) device, as well as a measurement circuit connected to the ST-FMR device. The sandwich structure 100 comprises a spin source layer 102 connected or connectable to a current source (not shown), a magnetic layer 104 and, sandwiched between the spin source layer 102 and magnetic layer 104, a magnetic insulating layer 106. The magnetic insulating layer prevents, either substantially or completely, passage of electrical current from the spin source layer to the magnetic layer.

In one embodiment, the ST-FMR device structure is Bi₂Te₃ (8 nm)/NiO (d)/Ni₈₁Fe₁₉ (6 nm)/SiO₂ (2 nm)/Ta (1.5 nm) samples. The ST-FMR technique was used to quantify the magnon-mediated torque of such an ST-FMR device. The thickness of Bi₂Te₃ was chosen to be 8 nm in this case as Bi₂Te₃ was found to exhibit the highest spin torque efficiency at this thickness. The magnetic layer may be Ni₈₁Fe₁₉, which shows in-plane magnetic anisotropy, a feature required for ST-FMR characterisation.

An in-plane radio frequency current I_{rf} with frequencies f ranging from 7 GHZ to 12 GHz may be applied along the x-axis using a signal generator. The oscillating spin currents, which mainly originate from topological surface states, are generated in the Bi₂Te₃ layer and converted into a magnon current through the interfacial exchange interaction between Bi₂Te₃/NiO. The magnon currents pass through the NiO layer and exert oscillating magnon torques on the top Ni₈₁Fe₁₉ layer including both the damping-like torque γτ_{DL} (m×σ×m) and the field-like torque γτ_{FL} (m×σ), where m and σ are the unit vectors of the magnetization of Ni₈₁Fe₁₉ and the induced magnon spin polarisation from the NiO layer respectively, γτ_{DL} and γτ_{FL} are the damping-like and field-like effective field induced by magnon or spin currents. The I_{rf} also exerts the Oersted field torque −γ (m×H_{Oe}) on the Ni₈₁Fe₁₉ layer. These torques, which can be decomposed into the out-of-plane oriented torque τ_{⊥} and in-plane oriented torque τ_{∥}, drive the magnetisation of the Ni₈₁Fe₁₉ layer away from equilibrium and into precession, thereby changing the anisotropic magnetoresistance of the Ni₈₁Fe₁₉ layer. Consequently, the mixing of the change of the device resistance with Inf gives rise to a d.c. voltage which is measured as the ST-FMR signal Vₘᵢₓ by a lock-in amplifier. It is noteworthy that the propagation of I_{rf} along the Ni₈₁Fe₁₉ layer has no impact on the results of the ST-FMR due to the absence of net torques in Ni₈₁Fe₁₉ itself. FIG. 1b shows the typical ST-FMR signals from the sandwich structure of Bi₂Te₃ (8 nm)/NiO (25 nm)/Ni₈₁Fe₁₉ (6 nm). The ST-FMR signals were measured at 9 GHz. The signals may be decomposed into two parts (as indicated by the solid lines) Vₘᵢₓ=V_{S}F_{S}+V_{A}F_{A}, wherein V_{S}F_{S} is the symmetric component arising from the damping-like torque and V_{A}F_{A} is the anti-symmetric component arising from the field-like torque as well as the Oersted field induced torque. The symmetric component indicates that the Ni₈₁Fe₁₉ magnetisation experiences a sizable damping-like torque induced by magnon currents. The amplitude of symmetric component may not be identical when the external field reverses, where the small out-of-plane component of the external field generates in-plane torque which contributes to the symmetric signal. This contribution can be excluded by averaging the amplitude of symmetric signals. Since the topological surface states may contribute to the antisymmetric component of the ST-FMR signal, it is insufficient to assume that the antisymmetric component arises only from the Oersted field induced torque in the determination of the spin torque efficiency. There is hence a need to use only the symmetric component to evaluate the magnon torque efficiency θ_{ST} based on

$${V}_{S} {F}_{S} = - \frac{{I}_{rf} γ cos φ}{4} \frac{dR}{d φ} {τ}_{DL} \frac{1}{Δ} {F}_{S} \qquad ( 1 )$$

$${σ}_{s} = \frac{2 e}{ℏ} \frac{{τ}_{DL} {M}_{s} {t}_{Py}}{E} \qquad ( 2 )$$

$${θ}_{ST} = \frac{{σ}_{s}}{σ} \qquad ( 3 )$$

where γ is the gyromagnetic ratio, φ=40° is the external field direction with respect to the current I_{rf} direction, dR/dφ is the angle-dependent magnetoresistance at φ. Δ=0.5γα(2μ₀Hₑₓₜ+μ₀M_{eff}) is the linewidth of ST-FMR signal in the frequency spectrum, where α and M_{eff} are the damping constant and effective magnetization of Ni₈₁Fe₁₉ respectively, μ₀ is the vacuum permeability. σₛ is the spin Hall conductivity of spin source, Mₛ is the saturation magnetization of Ni₈₁Fe₁₉ which is determined to be 6.8×10⁵ A/m by vibrating sample magnetometer (VSM), t_{Pγ}=6 nm is the thickness of Ni₈₁Fe₁₉, σ is the electric conductivity of the spin source, and E is the microwave field applied to the device. From equation (1), the damping-like effective field τ_{DL} exerted on the Ni₈₁Fe₁₉ magnetization may be obtained, which is 7.6×10⁻³ mT. The microwave field E can be calculated by E=jₛ/σₛ, where jₛ is the microwave current density in the spin source. Based on the calculated E and τ_{DL}, θ_{ST} of the Bi₂Te₃ (8 nm)/NiO (25 nm)/Ni₈₁Fe₁₉ (6 nm) sample was evaluated to be 0.33, comparable to or larger than that of electron-mediated spin torques.

FIG. 1c summarises the d dependence of θ_{ST} in Bi₂Te₃ (8 nm)/NiO (d)/Ni₈₁Fe₁₉ (6 nm) samples. The curve shows a typical antiferromagnetic magnons-related behaviour: a sharp decrease up to 3 nm, followed by a gradual increase, reaching a peak value as the NiO layer becomes thicker (d ~25 nm). The sudden decrease of θ_{ST} is ascribed to the blocking of the electron-mediated spin currents by the non-magnetic NiO layer. This is evidenced by the lack of visible enhancement in the coercivity of the Ni₈₁Fe₁₉ layer, as shown in the inset of FIG. 1c. With further increase of d, the coercivity of the Ni₈₁Fe₁₉ layer gradually increases, indicating the formation of the antiferromagnetic ordering in the NiO layer, which is important for magnon transports in NiO. Consequently, θ_{ST} increases due to the enhanced contribution of antiferromagnetic magnons and reaches a peak value at d=25 nm. An exponential decay function θ_{ST}=θ₀exp(−(d−d₀)/lₘ) was used to fit the magnon diffusion length lₘ and the value was determined to be 26.6 nm. Terahertz emission measurements were also carried out on Bi₂Te₃ (6 nm)/NiO (d)/Ni₈₁Fe₁₉ (3 nm)/SiO₂ (3 nm) samples. The terahertz emission amplitude reveals a similar trend as θ_{ST}, which verifies the observation of magnon torques.

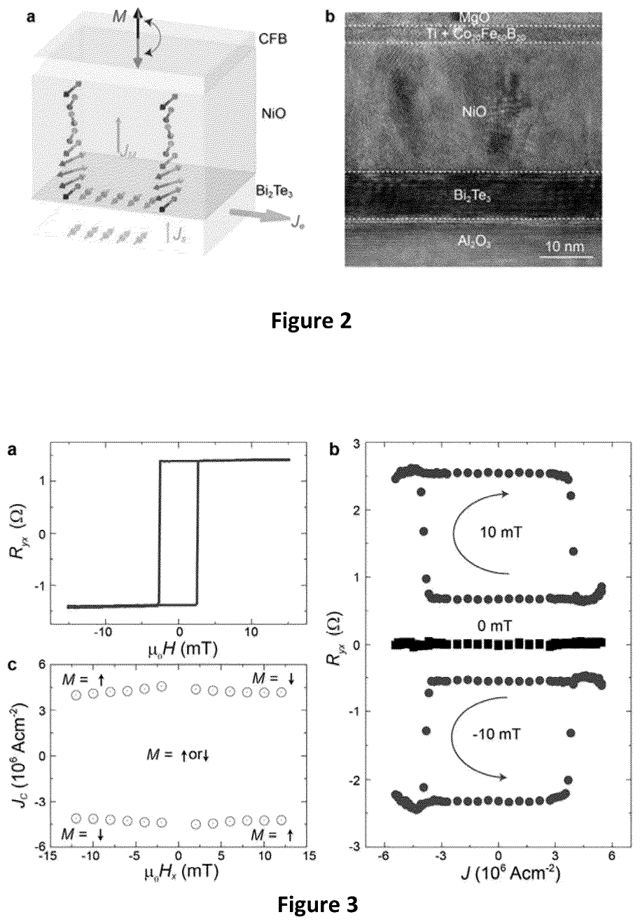

In some embodiments, magnon torques may be used for efficient switching of a ferromagnetic layer with PMA. A film of Ti (2 nm)/Co₂₀Fe₆₀B₂₀ (0.9 nm)/MgO (2 nm)/Ta (1.5 nm), abbreviated as CoFeB, was deposited on top of Bi₂Te₃ (8 nm)/NiO (25 nm) using magnetron sputtering. In the Bi₂Te₃/NiO/CoFeB structure, the nonequilibrium electron spin current Jₑ in the Bi₂Te₃ layer may be converted into magnon currents J_{M} in NiO through an interfacial exchange interaction. Magnon currents may enable the switching of the CoFeB layer. FIG. 2a illustrates a schematic of magnon-torque switching of a CoFeB layer, wherein CoFeB exhibits PMA.

FIG. 2b provides high-resolution transmission electron microscopy (TEM) image of a typical Bi₂Te₃ (8 nm)/NiO (25 nm)/CoFeB sample. Clear and well-defined interfaces (marked by a dotted line) are observed not only at the Bi₂Te₃/NiO interface but also at the NiO/CoFeB interface. The high-quality interfaces as indicated by the white lines may play an important role in the generation and propagation of magnon currents.

In some embodiments, a film of Bi₂Te₃ (8 nm)/NiO (25 nm)/CoFeB is patterned into Hall bar devices with a width of 10 μm. The PMA of the CoFeB layer is confirmed by a square-shaped anomalous Hall loop as illustrated in FIG. 3a. No exchange bias has been observed, which may a result of the isolation of NiO and CoFeB layer using Ti. To measure the magnon-induced magnetisation switching, a current pulse with a 100 μs pulse width and different amplitudes to the Hall bar devices was injected and the Hall voltage was probed using a small DC current of 0.1 mA after each current pulse, under varying in-plane magnetic fields.

FIG. 3b illustrates a clear switching window, which may indicate that the CoFeB layer may be switched by magnon-mediated spin torques. The critical switching current density J_{C} is 4.1×10⁶ A/cm², which is smaller than or comparable to those of electron-mediated spin torques. The switching is clockwise for a positive in-plane external field of 10 mT and anticlockwise for a negative external field of −10 mT, which is similar to the typical spin torque-induced PMA switching behaviour. The switching loop is absent without the assisted external field, which may indicate that magnon torque induced switching also requires an external magnetic field to break the symmetry.

FIG. 3c illustrates the switching phase diagram, wherein the critical current density decreases slightly with an increasing external field. This behaviour is similar to that in electron-mediated switching. SOT switching measurements on Bi₂Te₃/CoFeB samples may also be performed to demonstrate a similar behaviour as Bi₂Te₃/NiO/CoFeB.

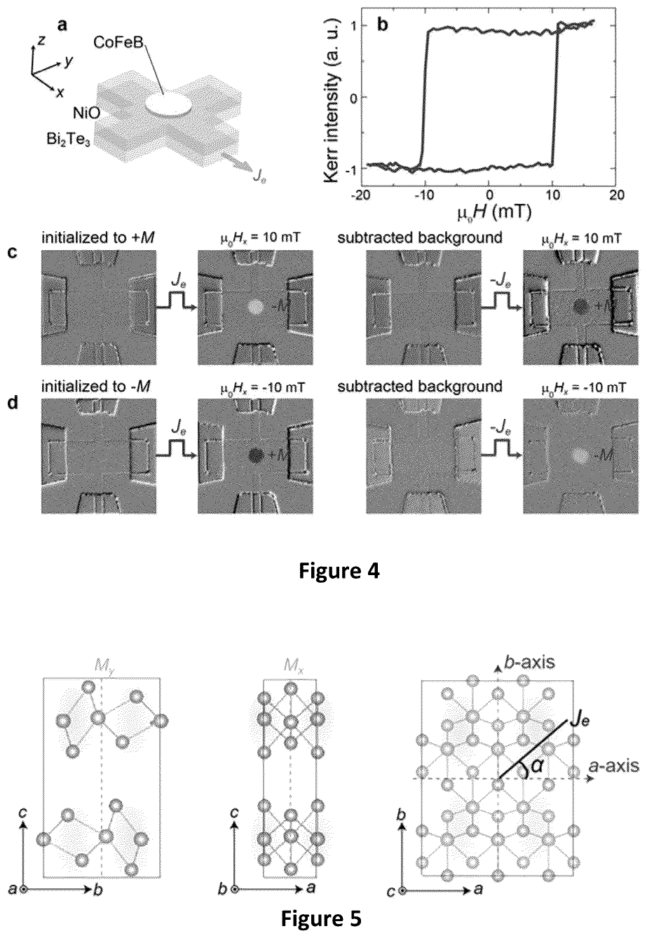

In some embodiments, the magnon torque-induced switching is demonstrated by pattering a CoFeB layer into magnetic dots with a radius of 5 μm in the centre of the Hall bar cross. Thus, the magnetic layer may comprise a magnetic dot at a centre of the rectangular or cross-shape. This further excludes the possible influence from current shutting into Ti/CoFeB layers. A schematic of such a patterning is illustrated in FIG. 4a.

Polar magneto-optical Kerr effect (MOKE) microscopy may be utilised to measure CoFeB switching. The magnetic field μ₀H dependence of the magnetisation M is first measured to verify the PMA of CoFeB. FIG. 4b shows a square-shaped hysteresis loop which demonstrates the retention of PMA after dot patterning. FIGS. 4c and 4d show the switching measurement results. The magnetisation of CoFeB is first initialised in the +z direction and the background was subtracted. When a fixed magnetic field of 10 mT is applied along the +x direction to break the symmetry, the contrast of the CoFeB dot turns white upon injection of an electrical current pulse with a current density of 5.7×10⁶ A/cm² and a pulse width of 100 μs along the same direction, consistent with the switching of CoFeB magnetisation from the +z to −z direction. To enhance the contrast, the background is then subtracted and a current pulse of 6.2×10⁶ A/cm² was applied to the −x direction. This results in the contrast of the CoFeB dot changing from white to black, which may indicate the down to up switching of CoFeB magnetisation. FIG. 4d illustrates that the switching polarity is inverted on reversing the direction of the in-plane magnetic field, and the CoFeB magnetisation favours pointing up (down) for the positive (negative) current, which is consistent with the switching measurement results in FIG. 3b. The imaged switching of the CoFeB magnetic dots unambiguously demonstrates that the magnon-mediate spin torque can switch the electrically isolated CoFeB dot with PMA.

In some embodiments, Bi₂Te₃ has been used as a spin source layer, and an external assisting magnetic field along the current direction is required. This requirement of magnetic field complicates the device design and impedes the scalability. The magnon current with out-of-plane spins (z-spins) can overcome the limitation of external magnetic fields. The z-spins can be created in low crystal-symmetry materials with at most one mirror plane and no n-fold (n>1) rotational invariance. Thus, the spin source layer can have a crystal structure selected to generate out-of-plane spin and, in some instances, comprises or is a bilayer structure (i.e. multiple layers, such as two van der Waals materials or a symmetry broken layer and a centrosymmetric layer). FIG. 5 illustrates the crystal symmetry of WTe₂. Its glide symmetry is broken along the low-symmetry a-axis, but the mirror symmetry along the b-axis is preserved. In this case, the z-spins can be obtained for the current injected along the a-axis of WTe₂.

In some embodiments, the spin source layer used was WTe₂ with out-of-plane spins. In the WTe₂/NiO/PMA structure, the out-of-plane spins generated from WTe₂ layer can pass through NiO layer and enable the deterministic switching of PMA at zero magnetic field.

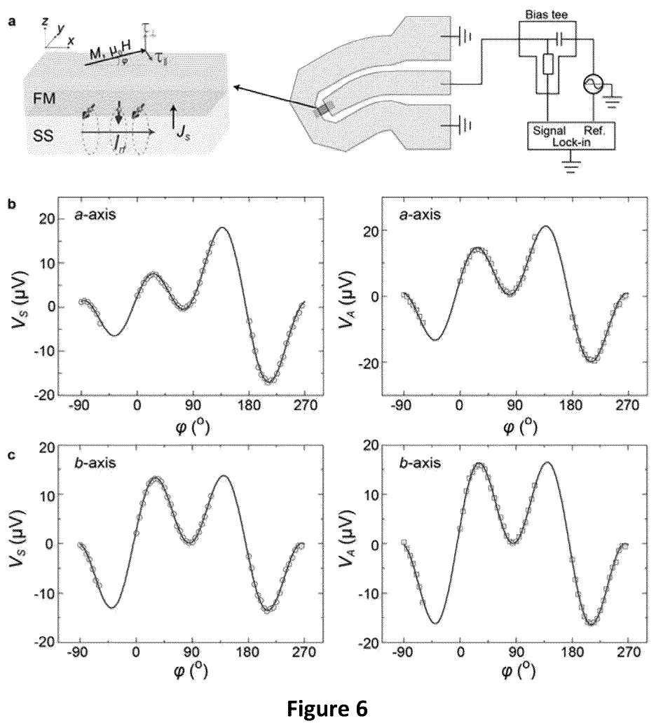

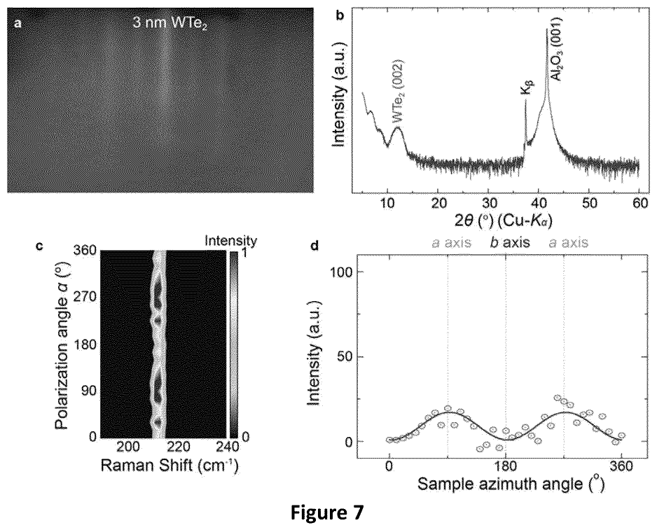

The ST-FMR technique was used to quantify both in-plane and out-of-plane polarised spin currents generated from the spin source (SS) layer. FIG. 6a provides a schematic diagram of the ST-FMR setup with the film structure, which comprises the SS layer and the FM layer. In some embodiments, the FM layer is a 6 nm-thick Ni₈₁Fe₁₉ layer, and the SS layer is PtTe₂, WTe₂, or PtTe₂/WTe₂ with various thicknesses. An in-plane radio frequency (rf) current I_{rf} with frequencies f ranging from 4 GHz to 9 GHz and a power of 15 dBm is applied across the x-axis using a signal generator. The current injection direction has different angles α relative to the a-axis of the WTe₂ layer. The angle φ of the external magnetic field μ₀H with respect to the current direction (x-axis) was set to satisfy the ferromagnetic resonance condition. After applying I_{rf}, oscillating spin currents are generated in the SS layer and diffuse into the FM layer, thus exerting oscillating SOT on the adjacent magnetic moments including both the damping-like SOT [m×(σ×m)] and the field-like SOT (σ×m), where m and σ are the magnetisation in Ni₈₁Fe₁₉ and the induced spin from the SS layer, respectively. I_{rf} exerts the Oersted field torque (m×H_{Oe}) on the Ni₈₁Fe₁₉ layer. These combined torques, which can be decomposed to the out-of-plane oriented torque τ_{⊥} and in-plane oriented torque τₗ, drive the magnetisation of the Ni₈₁Fe₁₉ layer away from equilibrium and into precession, yielding the change the anisotropic magnetoresistance. Consequently, the change of the device resistance mixing with I_{rf} gives rise to a d.c. voltage which is measured as the ST-FMR signal Vₘᵢₓ by a lock-in amplifier.

In one embodiment, a low crystal-symmetry material is used as a spin source layer to drive magnon torques. This is not limited to WTe₂, but may work for any material as long as out-of-plane spins can be generated. The high crystalline quality and smooth surface topography of WTe₂ are confirmed by combined characterisations of RHEED, and X-ray diffraction (XRD). FIG. 7a illustrates the RHEED spectra demonstrating the high crystalline quality and smooth surface topography of WTe₂. FIG. 7b illustrates the XRD spectra of WTe₂, also showing the same. The crystal axes of the WTe₂ films may be distinguished by polarised Raman spectroscopy, as shown in FIG. 7c, and by terahertz signal as shown in FIG. 7d.

ST-FMR measurements of WTe₂ (8 nm)/Ni₈₁Fe₁₉ (6 nm) were carried out with a current applied along the a-axis to provide evidence that WTe₂ can provide out-of-plane polarised spin current. Vₘᵢₓ appears to be quite different in both shape and amplitude for the positive and negative external magnetic fields. This may be attributed to additional z-spin-induced damping-like (m×z×m) and field-like (m×z) torques. The in-plane and out-of-plane effective spin torque efficiencies were extracted to be θ_{y}=0.15 and θ_{z}=−0.034, respectively. The room temperature resistivity ρₓₓ of the 8 nm WTe₂ film is 1123 μΩ·cm and thus the in-plane and out-of-plane spin Hall conductivities were determined to be σ_{s,y}=1.335×10⁴ (ℏ/2e) (Ωm)⁻¹ and σ_{s,z}=−0.3×10⁴ (ℏ/2e) (Ωm)⁻¹, respectively.

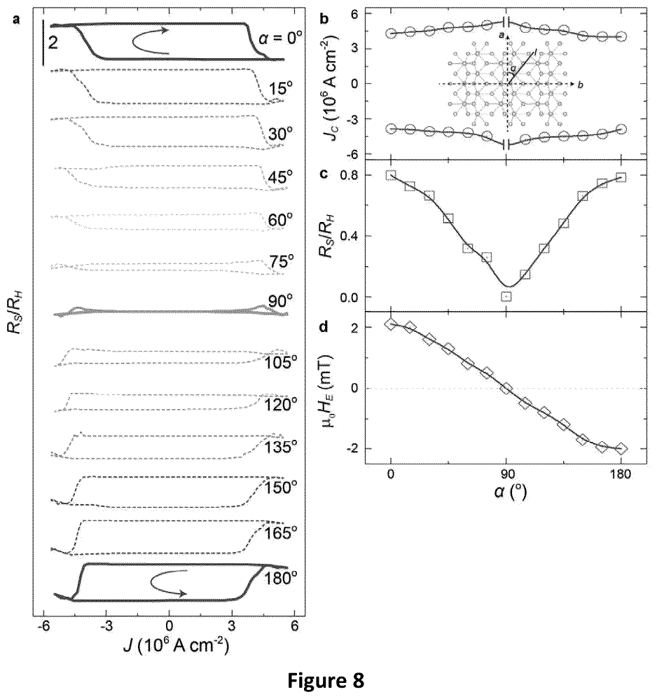

In some embodiments, a structure comprising NiO (25 nm)/Ti (2 nm)/Co₂₀Fe₆₀B₂₀ (0.9 nm)/MgO (2 nm)/Ta (1.5 nm) was deposited on top of WTe₂ (8 nm) using magnetron sputtering. CoFeB presents a good PMA. FIG. 8a illustrates the current-induced magnetisation switching of WTe₂ (8 nm)/NiO (25 nm)/CoFeB with the current applied along the different direction with respect to the a-axis of WTe₂ without any external field. A clear switching window with a critical current density J_{C} of 4×10⁶ A/cm² for samples along the low symmetry a-axis is observed which may suggest a field-free switching of PMA driven by magnon torques. FIGS. 8b-8d illustrate how J_{c} increases with the devices away from the a-axis. In addition, the switching ratio, which is characterised by the switching resistance change divided by the anomalous Hall resistance, decreases as the devices move away from a-axis. This suggests the magnon torques are related to the crystal symmetry of under layer WTe₂.

Field-free switching for devices with different NiO thicknesses was also performed. FIG. 9a provides a schematic of a magnon-mediated magnetisation switching based on the WTe₂/NiO/CoFeB sandwich heterostructures. The current is along the a-axis of WTe₂.

FIGS. 9b and 9c illustrate the switching ratio and critical switching current density in the WTe₂ (8 nm)/NiO (t)/CoFeB heterostructures. The switching ratio and critical switching current density exhibit opposite trends as the NiO thickness increases. In the magnon torque region, the switching ratio is maximum, and the critical current density is minimum for the device with 25 nm thick NiO. The z-spins generated in WTe₂ may excite magnon currents which carry out-of-plane polarised spin angular momentum and realise field-free magnon torque switching of PMA CoFeB.

In some embodiments, the spin source layer used may be a PtTe₂/WTe₂ heterostructure. The combination of both materials in a heterostructure may present out-of-plate spins and high spin Hall conductivity simultaneously. This may provide low power-consumption magnon-driven switching of PMA at zero magnetic field. New ways to manipulate PMA may also be realised, facilitating the development of low power-consumption MRAM using magnons.

### Example 1: Realisation of High Spin Hall Conductivities in PtTe₂/WTe₂ Bilayers

Spin currents generated from a single WTe₂ or PtTe₂ layer may first be quantified by the ST-FMR technique.

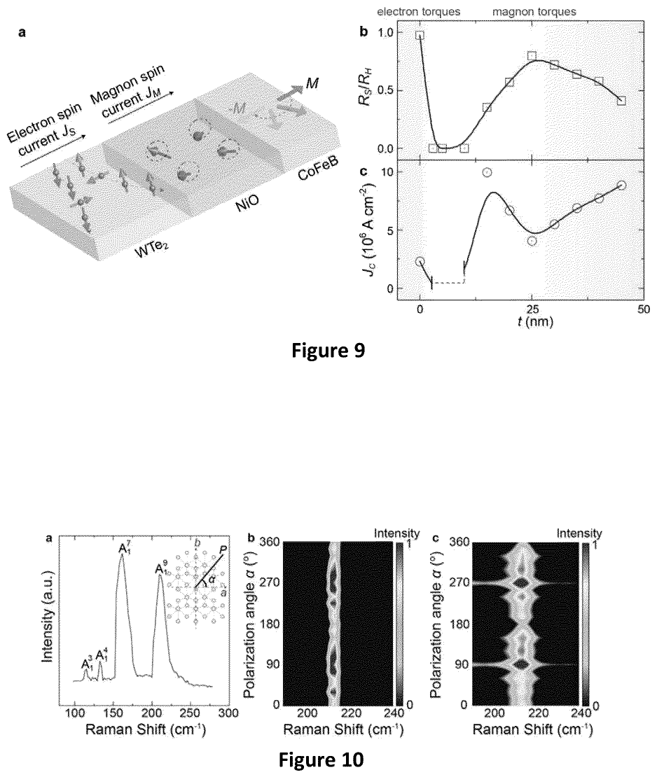

FIG. 10a illustrates the determination of the crystal axes of 8 nm WTe₂ films by polarised Raman. Polarised Raman measurements were carried out to determine if MBE-grown WTe₂ films have a preferred crystalline orientation. There are four dominant Raman-active peaks at 115, 133, 162, and 212 cm 1, which correspond to the

$${A}_{1}^{3} , {A}_{1}^{4} , {A}_{1}^{7} , and {A}_{1}^{9}$$

phonon modes, respectively. These peaks are consistent with previous reports of exfoliated WTe₂ thin flakes, confirming the T_{d} phase of our WTe₂ films. FIG. 10b presents the polarisation angle α (as defined in the inset of the FIG. 10a) dependence of Raman spectra, which was collected by rotating the sample relative to the incident laser. The mode of

$${A}_{1}^{9}$$

at 212 cm⁻¹ reaches its minimum at α=0°, 180°, and 360°, when the laser is along the low-symmetry a-axis. On the other hand, the maximum relative intensity appears at α=90° and 270°, when the laser is in parallel to the b-axis. Following the above method, the crystal axis of the PtTe₂ (2 nm)/WTe₂ (6 nm) bilayer was determined, as shown in FIG. 10c.

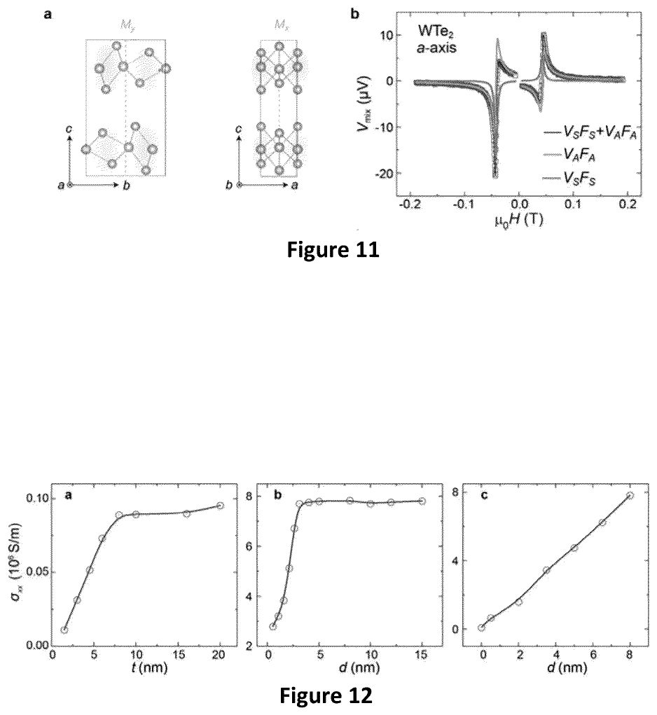

FIG. 11a illustrates that the glide symmetry may be broken along the low-symmetry a-axis, but the mirror symmetry along the b-axis is preserved in WTe₂. Both the y- and z-spins are generated for the current injected along the a-axis of WTe₂. WTe₂ (t)/Ni₈₁Fe₁₉ (6 nm), t=1.5, 3, 4.5, 6, and 8 nm, heterostructures were fabricated, where the Ni₈₁Fe₁₉ layer exhibits an in-plane magnetic anisotropy for ST-FMR measurements.

FIG. 11b illustrates the ST-FMR signal Vₘᵢₓ for the WTe₂ (8 nm)/Ni₈₁Fe₁₉ (6 nm) sample with the current applied along the a-axis. Vₘᵢₓ is asymmetric for the positive and negative external magnetic fields, owing to additional z-spin-induced damping-like [m×(z×m)] and field-like [(m×z)] torques, where m is the unit vector along the magnetisation.

The Vₘᵢₓ signal can be decomposed by fitting Vₘᵢₓ to

$${V}_{mix} = {V}_{S} \frac{{Δ}^{2}}{{Δ}^{2} + {( {μ}_{0} H - {μ}_{0} {H}_{0} )}^{2}} + {V}_{A} \frac{Δ ( {μ}_{0} H - {μ}_{0} {H}_{0} )}{{Δ}^{2} + {( {μ}_{0} H - {μ}_{0} {H}_{0} )}^{2}}$$

where V_{S} and V_{A} are the amplitudes of the symmetric and antisymmetric Lorentzian components, respectively. V_{S} and V_{A} are proportional to τₗ and τ_{⊥} by

$${V}_{S} = - \frac{{I}_{rf}}{2} \frac{d R}{d φ} \frac{cos φ}{{α}_{G} γ ( 2 {μ}_{0} {H}_{0} + {μ}_{0} {M}_{eff} )} {τ}_{\vert \vert} and$$

$${V}_{A} = - \frac{{I}_{rf}}{2} \frac{d R}{d φ} \frac{cos φ \sqrt{1 + {μ}_{0} {M}_{eff} / {μ}_{0} {H}_{0}}}{{α}_{G} γ ( 2 {μ}_{0} {H}_{0} + {μ}_{0} {M}_{eff} )} {τ}_{⊥} ,$$

where dR/dφ is related to the anisotropic magnetoresistance in the Ni₈₁Fe₁₉ layer, μ₀M_{eff} is the out-of-plane demagnetisation field, μ₀H₀ is the resonance field, α_{G} is the Gilbert damping coefficient and γ is the gyromagnetic ratio.

To quantify the in-plane and out-of-plane effective spin efficiencies (θ_{y} and θ_{z}) of the WTe₂ (8 nm)/Ni₈₁Fe₁₉ (6 nm) sample, the relation V_{S} (−μ₀H)=−V_{y,DL}+V_{z,FL} and V_{S} (μ₀H)=V_{y,DL}+V_{z,FL} based on the symmetry argument was used, where V_{y,DL} and V_{z,FL} are the y-spins induced damping-like component and z-spins induced field-like component, respectively. Similarly, V_{A} (−μ₀H)=−V_{y,FL+Oe}+V_{z,DL} and V_{A} (μ₀H)=V_{y,FL+Oe}+V_{z,DL}, where V_{y,FL+Oe} is the sum of field-like component induced by the Oersted field and y-spins. V_{z,DL} is the z-spins induced damping-like component. This gives rise to:

$${V}_{z , FL} = \frac{{V}_{S} ( {μ}_{0} H ) + {V}_{S} ( - {μ}_{0} H )}{2} \qquad ( 4 )$$

$${V}_{y , DL} = \frac{{V}_{S} ( {μ}_{0} H ) - {V}_{S} ( - {μ}_{0} H )}{2} , \qquad ( 5 )$$

$${V}_{y , FL + O e} = \frac{{V}_{A} ( {μ}_{0} H ) + {V}_{A} ( - {μ}_{0} H )}{2} , \qquad ( 6 )$$

$${V}_{z , DL} = \frac{{V}_{A} ( {μ}_{0} H ) - {V}_{A} ( - {μ}_{0} H )}{2} . \qquad ( 7 )$$

The effective spin efficiencies can be calculated as

$${θ}_{y} = \frac{{V}_{y , DL}}{{V}_{z , FL}} \frac{e {μ}_{0} {M}_{S} {t}_{F M} {t}_{SS}}{ℏ} \sqrt{1 + \frac{- {H}_{eff}}{{H}_{res}}} , \qquad ( 8 )$$

$${θ}_{z} = \frac{{V}_{z , DL}}{{V}_{y , FL + O e}} \frac{e {μ}_{0} {M}_{S} {t}_{F M} {t}_{SS}}{ℏ} \qquad ( 9 )$$

where M_{S} is the magnetisation of Ni₈₁Fe₁₉, and t_{FM} and t_{SS} are the Ni₈₁Fe₁₉ and SS layer thickness, respectively. θ_{y} and θ_{z} of 8 nm WTe₂ were hence found to be 0.15 and −0.034, respectively. The negative Oz indicates the generation of down (up) spins for a positive (negative) current in our experimental geometry.

The angular φ dependence of Vₘᵢₓ was also evaluated. Vₘᵢₓ contributed by y- and z-polarised spins has different angle dependences, i.e. sin 2φ cos φ for y-polarised spins and sin 2φ for z-polarised spins. For a device comprising a WTe₂ (8 nm)/Ni₈₁Fe₁₉ (6 nm) bilayer (schematic provided in FIG. 6a), the φ dependence of V_{S} and V_{A} signals of the current along the a- and b-axis is shown in the FIGS. 6b and 6c, respectively. With currents along the a-axis, the curves can be fitted by the V_{S}=V_{y,DL} sin 2φ cos φ+V_{z,FL} sin 2φ and V_{A}=V_{y,FL} sin 2φ cos φ+V_{z,DL} sin 2φ, indicating the existence of the z-polarised spins. When the current is along the b-axis, the curves follow V_{S}=V_{y,DL} sin 2φ cos φ and V_{A}=V_{y,FL} sin 2φ cos φ, confirming the absence of z-polarised spins.

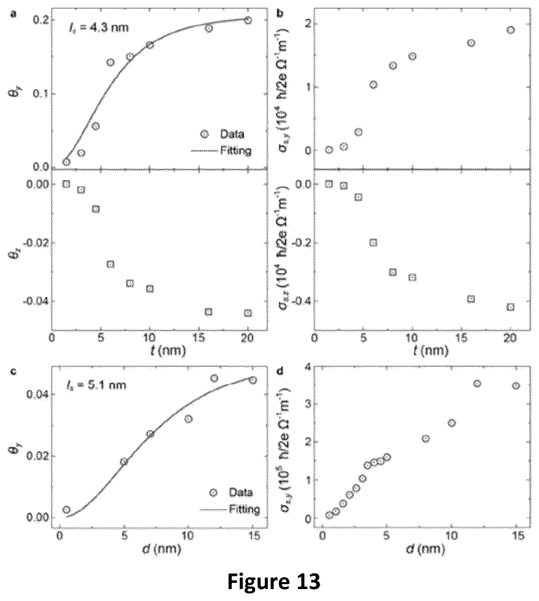

FIG. 12 provides the room-temperature resistivity ρₓₓ=1123.6 μω·cm of WTe₂. FIG. 13 shows the thickness dependence of spin efficiencies. The spin Hall conductivities were evaluated to be σ_{s,y}=1.335×10⁴ (ℏ/2e) (Ω·m)⁻¹ and σ_{s,z}=−0.3×10⁴ (ℏ/2e) (Ω·m)⁻¹, respectively. θ_{s,y} of WTe₂ was found to be an order of magnitude smaller than those in other spin-source materials.

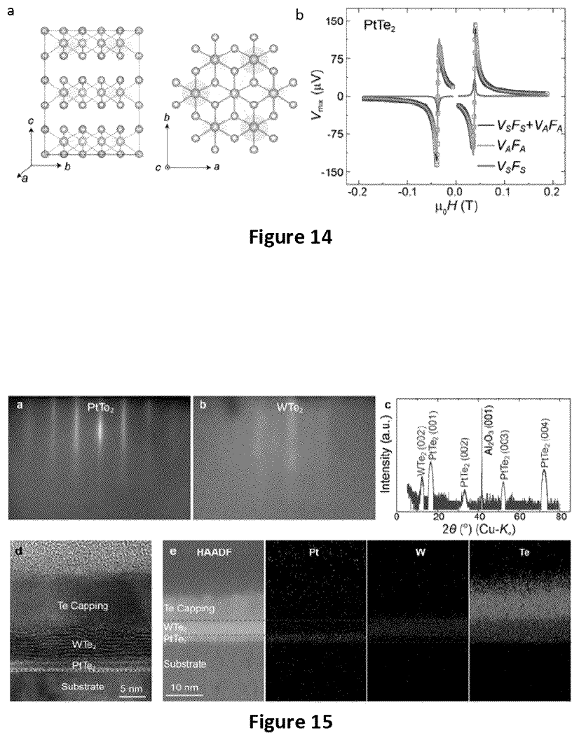

The full space group notation of PtTe₂ is P3̅m1, which has a hexagonal crystal structure. FIG. 14a shows a 3-fold rotation axis about the c-axis. Such symmetries forbid the presence of z-spins in PtTe₂. FIG. 14b provides a representative ST-FMR spectrum of a PtTe₂ (8 nm)/Ni₈₁Fe₁₉ (6 nm) device. Vₘᵢₓ shows nearly identical line shapes and amplitudes for the positive and negative magnetic fields, confirming the absence of z-spins. The in-plane spin Hall conductivity of σ_{s,y}=2.1×10⁵ (ℏ/2e) (Ω·m)⁻¹ was evaluated to be 16 times larger than that of WTe₂ (FIG. 13), which indicates PtTe₂ is an excellent y-spin source, but without z-spin.

In some embodiments, a heterostructure comprising WTe₂ and PtTe₂ provides a good platform for examining the spin-to-spin conversion, since large y-spins generated in PtTe₂ are injected into a low-symmetry crystal WTe₂ and can be converted to z-spins. FIG. 15 confirms the high crystalline quality and clear interface of PtTe₂/WTe₂ bilayer by reflection high-energy electron diffraction (RHEED), X-ray diffraction (XRD), and transmission electron microscopy (TEM).

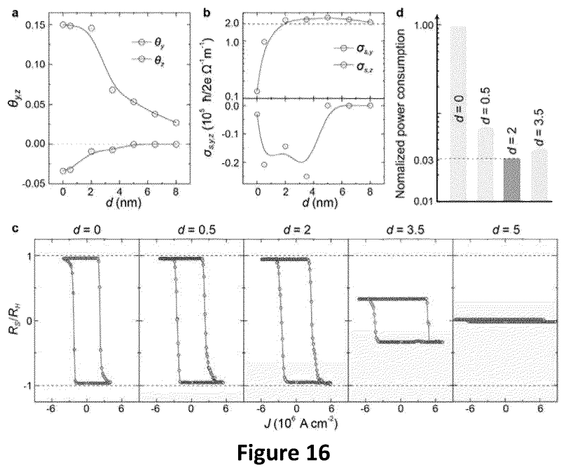

The total thickness of PtTe₂/WTe₂ heterostructures was fixed at 8 nm and the individual layer thickness of PtTe₂ and WTe₂ were changed accordingly. FIG. 16a summarises the thickness (d) dependence of Oy and Oz obtained from ST-FMR measurements of the PtTe₂ (d)/WTe₂ (8-d)/Ni₈₁Fe₁₉ (6 nm) samples. The magnitudes of both θ_{y} and θ_{z} decrease with thicker d. FIG. 16b shows the extraction of σ_{s,y} and σ_{s,z} of PtTe₂/WTe₂. The plots in FIG. 14b suggest σ_{s,y} first increases with increasing d, and then saturates at σ_{s,y}~2.32×10⁵ (ℏ/2e) (Ω·m)⁻¹ for d >2 nm. The PtTe₂/WTe₂ bilayer exhibits the highest σ_{s,y} among two-dimensional van der Waals materials, which is even comparable to that of topological insulators and heavy metals (Table 1). Moreover, σ_{s,z}=0.25×10⁵ (ℏ/2e) (Ω·m)⁻¹ is observed for d=3.5 nm.

TABLE 1
Comparison of effective spin efficiencies and conductivity of PtTe₂/WTe₂ with
other spin source materials. SHH is the abbreviation of second-harmonic Hall.

| | | | | | | |
|---|---|---|---|---|---|---|
| | | | | σ_{s, y} | σ_{s, z} | |
| SOT | | | ρₓₓ | (10³ [symbol] /2e) | (10³ [symbol] /2e) | Measurement |
| materials | θ_{y} | θ_{z} | (μΩcm) | (Ωm)⁻¹ | (Ωm)⁻¹ | techniques |

Two-dimensional materials with z-spins

| | | | | | | |
|---|---|---|---|---|---|---|
| WTe₂ | 0.029 | 0.013 | 385 | 8 | 3.6 | ST-FMR |
| WTe₂ | 0.0226 | — | 380 | 5.95 | — | ST-FMR |
| WTe₂ | 0.13 | 0.031 | 1769.7 | 7.36 | 1.76 | ST-FMR |
| WTe₂ (8 nm) | 0.15 | 0.034 | 1123 | 13.3 | 3 | ST-FMR |
| MoTe₂ | 0.032 | 0.0056 | 550 | 5.8 | 1.02 | ST-FMR |
| PtTe₂/WTe₂ | 0.068- | 0.007- | 29- | 97-235 | 14-25 | ST-FMR |
| (d = 0.5, | 0.149 | 0.032 | 154 | | | |
| 2, and 3.5 | | | | | | |
| nm) | | | | | | |

Antiferromagnetic materials with z-spins

| | | | | | | |
|---|---|---|---|---|---|---|
| RuO₂ | 0.049 | 0.0095 | 140 | 36 | 7 | ST-FMR |
| Mn₃GaN | 0.013 | 0.019 | 220 | 5.9 | 8.6 | ST-FMR |

Other two-dimensional materials

| | | | | | | |
|---|---|---|---|---|---|---|
| NbSe₂ | 0.005- | — | 166.7 | 3-7.8 | — | ST-FMR |
| | 0.013 | | | | | |
| PtTe₂ | 0.05- | — | 33- | 20-160 | — | ST-FMR |
| | 0.15 | | 333 | | | |
| PtTe₂ (8 nm) | 0.027 | — | 12.8 | 209 | — | ST-FMR |
| MoTe₂ | 0.13- | — | 542 | 24-64.4 | — | ST-FMR |
| | 0.35 | | | | | |

Topological insulators and conventional heavy metals

| | | | | | | |
|---|---|---|---|---|---|---|
| Bi₂Se₃ | 2-3.5 | — | 1754 | 110- | — | ST-FMR |
| | | | | 200 | | |
| BiₓSe₁₋ₓ | 8.6- | — | 12821 | 67-145 | — | ST- |
| | 18.6 | | | | | FMR/SHH |
| Pt | 0.056 | — | 20 | 280 | — | ST-FMR |
| Ta | −0.12 | — | 190 | −63 | — | ST-FMR |

### Example 2: High Spin Conductivities

High σ_{s,y} and σ_{s,z} in PtTe₂/WTe₂ bilayers may be used in the manipulation of perpendicular magnetisation. FIG. 16c shows the current-induced switching of PtTe₂ (d)/WTe₂ (8-d)/Ti (2)/Co_{0.2}Fe_{0.6}B_{0.2} (0.9)/MgO (2)/Ta (1.5) samples [PtTe₂ (d)/WTe₂ (8-d)/CoFeB, numbers in brackets are in nanometers] with the current along the a-axis of WTe₂ without any magnetic field. The CoFeB layer exhibits perpendicular magnetic anisotropy for all devices. For d=0, 0.5, and 2 nm, a complete magnetisation switching is observed (R_{S}/R_{H}~1 where R_{S} and R_{H} are the Hall resistance change in response to the SOT and magnetic field, respectively). The critical switching current density (J_{c}) of WTe₂ (d=0) is 2.25×10⁶ A/cm², which is one order smaller than that of conventional heavy metal Pt source (J_{c}~2.6×10⁷ A/cm²). With d increasing from 0 to 2 nm, Jₓ increases slightly to 2.6×10⁶ A/cm² despite an increase of 18 times in the charge conductivity (FIG. 12). With further increasing d, R_{S}/R_{H} decreases, and the switching loop vanishes for d ≥5 nm. The power consumption is calculated based on a two-current model. The result is shown in FIG. 16d. With the introduction of PtTe₂, the power consumption significantly decreases and reaches the minimum at d=2 nm. The power consumption of the d=2 nm sample is 33 times smaller than its parent material WTe₂ and 67 times smaller than that of the Pt-based control sample (Table 2) due to the significant increase of σ_{s,y} and σ_{s,z}.

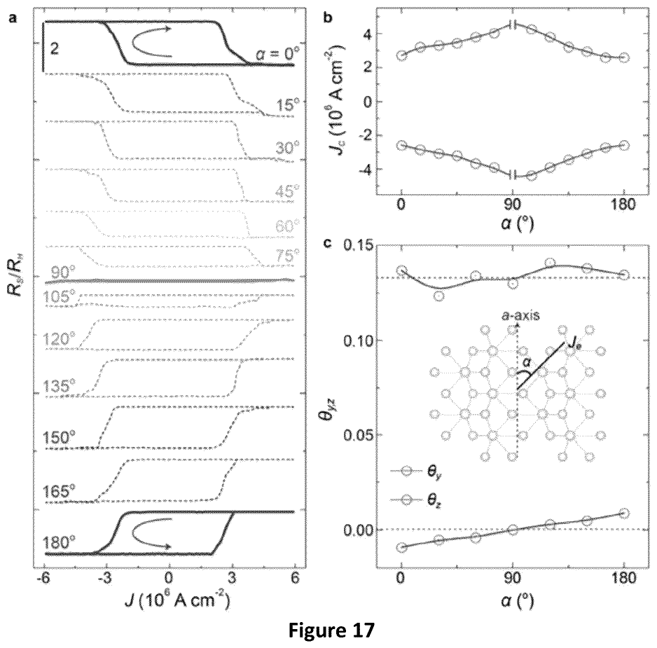

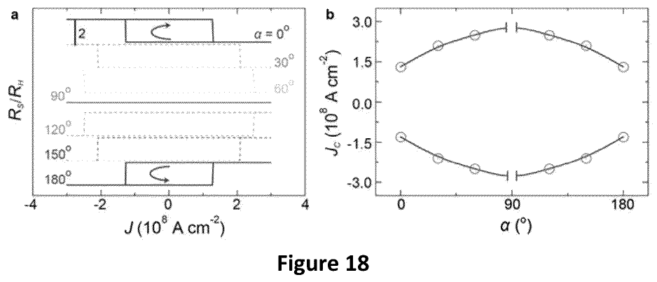

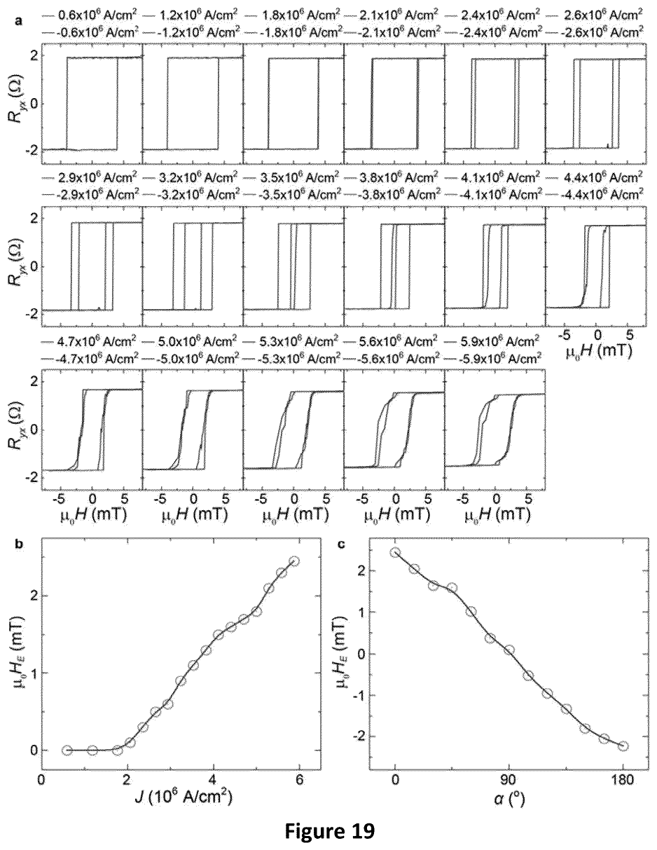

The devices with the different current injection angles α relative to the a-axis of the WTe₂ layer. The results are compatible with the crystal symmetry of WTe₂ and macro-spin simulations (FIGS. 17 and 18). A similar crystal-symmetry dependence of out-of-plane damping-like effective field (μ₀H_{E}) obtained from loop shift measurements is observed (FIG. 19). These results also confirm the z-spins are crucial for the field-free switching and can reduce J_{c} as well as the corresponding power consumption.

TABLE 2
Device parameters of the PtTe₂ (d)/WTe₂ (8-d)/CoFeB
and Pt (8 nm)/CoFeB heterostructures. Numbers in brackets
are in nanometers. I_{SS} is the current in the spin source layer,
I_{FM} is the current in the FM layer, ρ_{SS} is the resistivity
of the bilayer, and P is the power consumption of the device.

| | I_{SS} | I_{FM} | ρ_{SS} | P |
|---|---|---|---|---|
| Materials | (mA) | (mA) | (μΩ · cm) | (mW) |
| WTe₂ (8)/CoFeB (2.9) | 3.648 | 6.504 | 1123.6 | 103.7 |
| PtTe₂ (0.5)/WTe₂ (7.5)/CoFeB | 3.8736 | 0.9497 | 154 | 7.192 |
| (2.9) | | | | |
| PtTe₂ (2)/WTe₂ (6)/CoFeB (2.9) | 4.256 | 0.424 | 62.6 | 3.117 |
| PtTe₂ (3.5)/WTe₂ (4.5)/CoFeB | 7.392 | 0.339 | 28.9 | 4.114 |
| (2.9) | | | | |
| Pt (8)/CoFeB (2.9) | 41.6 | 2.98 | 45 | 208.6 |

The magnitude of σ_{s,z} appears to increase by about 8 times from −0.3×10⁴ (ℏ/2e) (Ω·m)⁻¹ for WTe₂ (8 nm) to −0.25×10⁵ (ℏ/2e) (Ω·m)⁻¹ for the heterostructure, PtTe₂ (3.5 nm)/WTe₂ (4.5 nm). This large increase of σ_{s,z} in the PtTe₂/WTe₂ bilayer suggests that the spin-to-spin conversion process occurs in the bilayer.

The heterostructure of two-dimensional van der Waals materials provides a trade-off between the electrical conductivity and effective spin efficiency which significantly increases σ_{s,y} and σ_{s,z}. In particular, the resulting z-spins guarantee all-electric manipulation of perpendicular magnetisation in low power consumption without any external magnetic field. The spin-to-spin conversion effect may therefore be utilised as an additional knob for spin current based devices.

### Example 3: MBE Growth of PtTe₂/WTe₂ Heterostructures

WTe₂, PtTe₂, and PtTe₂/WTe₂ films were grown on sapphire Al₂O₃ (001) substrates using a molecular beam epitaxy (MBE) system with a base pressure of 1×10⁻⁹ mbar. The Al₂O₃ substrates were first soaked in deionised water at 90° C. for 2 h and thermally annealed at 1000° C. for 3 h in a tube furnace with flowing oxygen gas. The heat-treated Al₂O₃ substrates were then degassed at ~800° C. for 1 h in the MBE chamber. High-purity W (4N) and Pt (4N) were evaporated from e-beam evaporators, and Te (5N) was evaporated from a Knudsen cell.

During the growth of the films, the substrate was maintained at ~250° C. The growth process was monitored by RHEED. The flux ratio of Te/(Pt or W) was set to be >30 to avoid possible Te deficiency in samples. The growth rate of the PtTe₂ and WTe₂ was around 0.05 nm/min. When the growth was finished, the samples were slowly cooled down to room temperature.

### Example 4: Magnetron Sputtering Growth of Ferromagnetic Layers

The MBE-grown films were immediately transferred into a magnetron sputtering chamber in the standard cleanroom environment with a well-controlled level of constant temperature and low humidity. The transfer time was strictly controlled under 3 min before pumping down the sputtering chamber. The perpendicularly magnetised ferromagnetic (FM) layer Ti (2 nm)/Co_{0.2}Fe_{0.6}B_{0.2} (0.9 nm)/MgO (2 nm)/Ta (1.5 nm) was subsequently sputtered on the top of the MBE films at room temperature. For the ST-FMR devices, the FM layer of Ni₈₁Fe₁₉ (6 nm)/SiO₂ (2 nm)/Ta (1.5 nm) with in-plane magnetic anisotropy was grown on the top of the MBE films at room temperature.

### Example 5: Device Fabrication

The films were patterned into 40×20 μm Hall bars by optical lithography and Ar ion milling. Ta (5 nm)/Cu (120 nm)/Ta (5 nm) electrodes were deposited by magnetron sputtering.

### Example 6: Fitting of Spin Diffusion Lengths of WTe₂ and PtTe₂

FIGS. 13a and 13b show t dependence of θ_{y} of WTe₂ and PtTe₂, respectively. With t increasing, θ_{y} increases and tends to saturate, which match well with θ_{y}=θ_{∞}[1−sech(t/lₛ)], where θ_{∞} is the spin efficiencies at infinite t, and lₛ is the spin diffusion length. From fitting, lₛ of WTe₂ and PtTe₂ are determined to be 4.3 nm and 5.1 nm, respectively.

### Example 7: Current-Induced Switching Measurements

A Keithley 6221 was used as the current source for d.c. and pulse measurements. For the pulse measurements, a 100 μs pulse was first applied, and then a small d.c. current of 50 ρA was applied to measure the Hall resistance. The Hall voltage was measured using a Keithley 2182A Nanovoltmeter.

### Example 8: Calculation of Power Consumption of SOT Devices

The power consumption of a model SOT device consisting of a SS layer (PtTe₂/WTe₂, and Pt) and a FM layer (CoFeB) were calculated by considering the current shunting into the CoFeB layer. The device length L=40 μm, width W=20 μm, CoFeB layer thickness D₁=2.9 nm and SS layer thickness D₂=8 nm were kept constant. The resistivity of CoFeB layer is PFM=227.7 μΩ·cm. The power consumption is calculated by

$$P = {I}_{F M}^{2} {ρ}_{F M} \frac{L}{{WD}_{1}} + {I}_{SS}^{2} {ρ}_{SS} \frac{L}{{WD}_{2}} ,$$

where I_{FM} and I_{SS} are the current flowing through the CoFeB layer and SS layer, respectively. The parameters to calculate power consumption are presented in Table 2.

### Example 9: Symmetry-Dependent SOT Measurements

Symmetry-dependent SOT measurements in PtTe₂ (2 nm)/WTe₂ (6 nm)/CoFeB were carried out. FIG. 17a shows the current-induced switching at zero magnetic field for different α ranging from 0 to 180°. Along the low-symmetry a-axis, i.e. α=0°, J_{C}=2.6×10⁶ A/cm² is sufficient to switch the CoFeB layer. As a increases, a larger J_{C} is required, and the corresponding change of anomalous Hall resistance (R_{S}/R_{H}) becomes smaller, as shown in FIGS. 17a and 17b. The switching loop quenches at α=90° when the current is along the b-axis in FIG. 17a. With further increasing α, the switching loop recovers gradually, and the switching polarity changes from clockwise to anticlockwise.

The ST-FMR measurements for PtTe₂ (2 nm)/WTe₂ (6 nm)/Ni₈₁Fe₁₉ (6 nm) were also carried out with different α. FIG. 17c shows the a dependence of θ_{y} and θ_{z}. In line with symmetry requirements, the magnitude of Oz shows the maximum value when the current is along the a-axis (0° and 180°) and becomes zero for the current along the b-axis (90°). In contrast to the strong dependence of θ_{z} on α, θ_{y} is rather independent of α.

### Example 10: Loop Shift Measurements

When a current is applied along the low-symmetry a-axis, z-polarised spins exert an out-of-plane damping-like effective field (μ₀H_{E}) on the adjacent FM layer. The effective field can be reflected by a horizontal shift in the anomalous Hall loops, R_{yx}-μ₀H hysteresis curve. R_{yx}-μ₀H hysteresis curves of the PtTe₂ (2 nm)/WTe₂ (6 nm)/CoFeB film were measured under different applied d.c. currents along the a-axis of WTe₂. As shown in FIG. 19a, the center of the R_{yx}-μ₀H curve of the PtTe₂ (2 nm)/WTe₂ (6 nm)/CoFeB sample shifts from zero to the right (left) side with the current density J≥2.1×10⁶ A/cm². With increasing J, μ₀H_{E} increases (FIG. 19b). FIG. 19c summarises the a dependence of μ₀H_{E}. The μ₀H_{E} decreases as the projection of the current along the b-axis grows.

### Example 11: Numerical Simulations

The Landau-Lifshitz-Gilbert equation in the presence of both in-plane and out-of-plane spins,

$$\frac{\partial m}{\partial t} = - γ m \times {H}_{eff} + {α}_{G} m \times \frac{\partial m}{\partial t} + {γξ}_{y} m \times ( m \times y ) + {γξ}_{z} m \times ( m \times z ) , \qquad ( 9 )$$

where m is the unit vector of the CoFeB magnetisation, γ is the gyromagnetic ratio, H_{eff} is the anisotropy field along the z-axis, α_{G} is the damping constant, y and z are the unit vector along the y-axis and z-axis, respectively, which denote the in-plane and out-of-plane spin directions.

The coefficient of damping-like torque by the in-plane and out-of-plane spins is expressed by

$${ξ}_{y , z} = \frac{ℏ}{2 e} \frac{{θ}_{y , z} {J}_{e}}{{M}_{S} {t}_{F M}} ,$$

where ℏ and e are the reduced Planck constant and the electron charge, respectively, M_{S} is the saturation magnetisation of the CoFeB layer, and try is the thickness of CoFeB.

The following parameters were used: the anisotropy field H_{eff}=K_{U}/M_{S}, where M_{S}=600×10³ A m⁻¹ and anisotropy energy density K_{U}=3×10⁵ J m⁻³, t_{FM}=0.9 nm and α_{G}=0.01. For θ_{y} and θ_{z}, the values extracted from ST-FMR measurements were used. The result is shown in FIG. 18. With increasing α from 0 to 90°, J_{C} increases, and the switching loop disappears at α=90°. When a further increases from 90 to 180°, the switching loop reappears, and its polarity changes from clockwise to anticlockwise.

Commercial applications include memory, magnon-based spintronics devices, logic, high-frequency devices, and neuromorphic computing comprising a switching device as described above.

### Example 12: Sample Preparation

Bi₂Te₃, and WTe₂ films were grown on sapphire Al₂O₃ (001) substrates using a molecular beam epitaxy (MBE) system with a base pressure of 1×10⁻⁹ mbar. The heat-treated Al₂O₃ substrates were then degassed at ~800° C. for 1 h in the MBE chamber. High-purity Bi (6N) and Te (5N) were evaporated from Knudsen effusion cells. The W (4N) was evaporated from e-beam evaporators. During the growth of the Bi₂Te₃ or WTe₂ films, the substrate was maintained at ~250° C., The growth process was monitored by reflection high-energy electron diffraction (RHEED). The flux ratio of Te/(Bi or W) was set to be >30 to avoid possible Te deficiency in samples. The growth rate of the Bi₂Te₃ and WTe₂ was around 0.05 nm/min. When the growth was complete, the samples were slowly cooled down to room temperature.

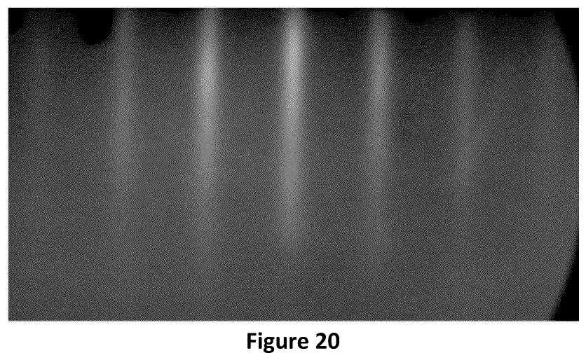

FIG. 20 illustrates the RHEED patterns of an 8 nm Bi₂Te₃ film. The sharp “1×1” diffraction streaks indicate the high crystalline quality and smooth surface of the Bi₂Te₃ films grown on sapphire substrates.

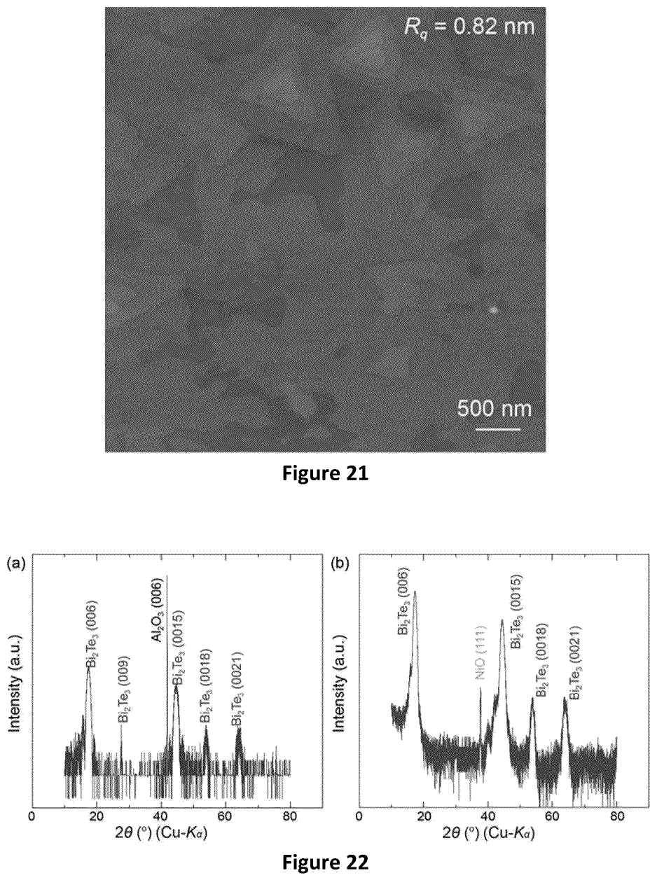

FIG. 21 illustrates an atomic force microscope (AFM) image of an 8 nm Bi₂Te₃ film. The root-mean-square (RMS) roughness (R_{α}) is ~0.82 nm. For an average grain size of 500-1000 nm, the low RMS roughness indicate the high crystalline quality and smooth surface of the films grown on sapphire substrates.

FIG. 22 illustrates the X-ray diffraction spectroscopy of (a) an 8 nm Bi₂Te₃ and (b) an 8 nm Bi₂Te₃/50 nm NiO film. The (00n) peaks of the Bi₂Te₃ layer have been observed, indicating that the MBE-grown Bi₂Te₃ films are highly ordered. It also shows the dominant NiO(111) peak.

The combined characterisation data presented in FIGS. 20-22 confirm the smooth surface topography and high crystalline quality of MBE-grown Bi₂Te₃ films.

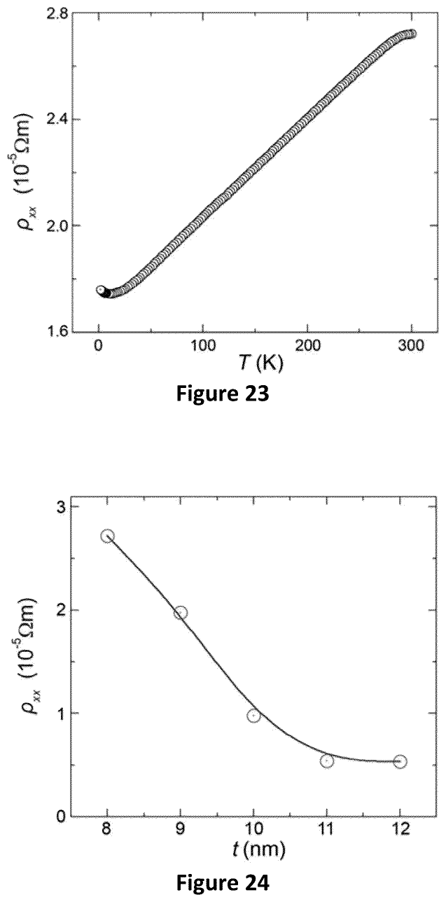

The transport measurements of MBE-grown Bi₂Te₃ films were also performed. FIG. 23 illustrates a temperature dependent resistivity ρₓₓ of an 8 nm Bi₂Te₃ film. The Bi₂Te₃ sample shows a metallic behaviour at high temperature (T) and an insulating ground state at low T. This insulating ground state is a result of the electron-electron interaction in topological insulator thin films. FIG. 24 illustrates resistivity ρₓₓ as a function of Bi₂Te₃ thickness t. Thinner Bi₂Te₃ films are more resistive, consistent with the effect of reduced dimensionality.

After Bi₂Te₃ deposition, the MBE-grown films were immediately transferred into a magnetron sputtering chamber in the standard cleanroom environment with a well-controlled level of constant temperature and low humidity. The transfer time was strictly controlled under 3 min before pumping down the sputtering chamber. The perpendicularly magnetised ferromagnetic layer Ti (2 nm)/Co_{0.2}Fe_{0.6}B_{0.2} (0.9 nm)/MgO (2 nm)/Ta (1.5 nm) was subsequently sputtered on the top of the MBE films at room temperature. For the ST-FMR devices, the ferromagnetic layer of Ni₈₁Fe₁₉ (6 nm)/SiO₂ (2 nm)/Ta (1.5 nm) with in-plane magnetic anisotropy was grown on the top of the MBE films at room temperature. The thickness of the magnetic insulating layer may be selected to maximise spin torque ferromagnetic resonance. The NiO films were directly deposited by radiofrequency magnetron sputter from a NiO target at 3 mTorr Argon pressure.

Ta (5 nm)/Cu (120 nm)/Ta (5 nm) electrodes were deposited by magnetron sputtering. For the ST-FMR devices, the films were patterned into rectangular microstrips with the width of 27.5-32.5 μm and length of 10-15 μm by photolithography and ion milling. Then, the electrodes were fabricated by photolithography, magnetron sputter, and lift-off process. For the switching devices, the films were patterned into Hall bar devices with a width of 10 μm and a length of 20 μm using photolithography and ion milling. For the switching devices measured by MOKE, CoFeB magnetic dots were patterned by laser writer and ion milling followed by deposition of 6 nm thick SiO₂ layer to protect devices from oxidisation.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Although this disclosure describes or illustrates particular embodiments as providing particular advantages, particular embodiments may provide none, some, or all of these advantages.

1. A magnon-mediated spin torque switching device, comprising:
a. a spin source layer connected or connectable to a current source;
b. a magnetic layer; and
c. a magnetic insulating layer between the spin source layer and the magnetic layer, for preventing passage of electrical current from the spin source layer to the magnetic layer.

2. The switching device of claim 1, wherein the spin source layer is a metallic layer or a topological material such as a topological insulator or Weyl semimetal.

3. The switching device of claim 1, wherein the spin source layer is 8 nm thick.

4. The switching device of claim 1, wherein the spin source layer comprises at least one of BiSb, Bi₂Se₃, Bi₂Te₃, Sb₂Te₃, MoTe₂, WTe₂, TaIrTe₄, and PTe₂.

5. The switching device of claim 1, wherein the spin source layer has a crystal structure selected to generate out-of-plane spin.

6. The switching device of claim 1, wherein the spin source layer comprises a bilayer.

7. The switching device of claim 6, wherein the bilayer comprises two van der Waals materials.

8. The switching device of claim 6, wherein the bilayer comprises heterostructures comprising layers of different crystal symmetries.

9. The switching device of claim 8, wherein the bilayer comprises a symmetry broken layer and a centrosymmetric layer.

10. The switching device of claim 9, wherein the bilayer is a WTe₂/PTe₂ heterostructure.

11. The switching device of claim 1, wherein a thickness of the magnetic insulating layer is selected to maximise spin orbit torques.

12. The switching device of claim 1, wherein the magnetic insulating layer is between 1 nm and 40 nm thick, preferably between 20 nm and 30 nm thick, and more preferably around 25 nm thick.

13. The switching device of claim 1, wherein the spin source layer and magnetic insulating layer form a rectangular or cross-shape.

14. The switching device of claim 13, wherein the magnetic layer comprises a magnetic dot at a centre of the rectangular or cross-shape.

15. The switching device of claim 1, wherein the magnetic insulating layer comprises NiO or other metals or transition metal oxides.

16. The switching device of claim 1, wherein the other metals or transition metal oxides comprise one of the following metals or transition metal oxides: Fe₂O₃, CoO, Cr₂O₃, MnO₂, RuO₂, BiFeO₃, DyFeO₃, TmFeO₃, YbFeO₃, CuMnAs, MnTe, MnTe₂, CrSb, and Mn₂Au.

17. The switching device of claim 1, wherein the magnetic layer is a ferromagnetic layer with perpendicular magnetisation.

18. Memory comprising:
a magnon-mediated spin torque switching device according to claim 1;
a current source connected to the spin source layer; and
a reader for reading a magnetisation direction of the magnetic layer.

19. The memory of claim 18, being a magnetoresistive random access memory (MRAM) device.

20. The memory of claim 19, wherein the magnetoresistive random access memory (MRAM) device comprises magnetic tunnel junctions.
